(19) United States
(12) Patent Application Publication
(10) Pub. No.: US 2025/0343495 A1
(43) Pub. Date: Nov. 6, 2025

(54) FLUX ESTIMATOR

(71) Applicant: Edwards Limited, Burgess Hill, Sussex (GB)

(72) Inventors: Richard Lee Harkin, Burgess Hill, Sussex (GB); James Alexander Haylock, Burgess Hill, Sussex (GB); Stephen James Thickett, Farnham Surrey (GB); Cedric Stephane Ngana Mbianji, Eastbourne Sussex (GB); Jian Li, Eastbourne Sussex (GB)

(21) Appl. No.: 18/854,375

(22) PCT Filed: Apr. 6, 2023
(86) PCT No.: PCT/GB2023/050917

§ 371 Date: Oct. 4, 2024

(30) Foreign Application Priority Data
Apr. 7, 2022 (GB) 2205118.9

(51) Int. Cl. H02P 23/14; G01R 31/34

(52) U.S. Cl. CPC H02P 23/14; G01R 31/34

(57) ABSTRACT

A flux estimator for estimating an air-gap flux in an electric motor includes a resistance compensation stage having a first multiplying digital-to-analogue converter, and an inductance compensation stage having a second multiplying digital-to-analogue converter. The flux estimator determines a first gain (Ku) for compensating for a stator resistance (Ra); and a second gain (KLa) for compensating a stator inductance (La). The first gain (Ku) is supplied to the first multiplying digital-to-analogue converter to generate a first output signal (VIAR) providing a scaled representation of the voltage drop across the stator resistance (Ra) per phase. The second gain (KLa) is supplied to the second multiplying digital-to-analogue converter to generate a second output signal (IA_LA) providing a scaled representation of the stator inductance (La) per phase. An air-gap flux estimation signal (PSI_MON) is generated in dependence on the first output (VIAR) and the second output (IA_LA).

### CROSS-REFERENCE OF RELATED APPLICATION

This application is a Section 371 National Stage Application of International Application No. PCT/GB2023/050917, filed Apr. 6, 2023, and published as WO 2023/194734 A1 on Oct. 12, 2023, the content of which is hereby incorporated by reference in its entirety and which claims priority of British Application No. 2205118.9, filed Apr. 7, 2022.

### FIELD

The present disclosure relates to a flux estimator. The flux estimator is suitable for estimating an air-gap flux for an electric motor. Aspects of the present invention also relate to a motor control unit; a control system; and a pump.

### BACKGROUND

It is known to estimate the air-gap flux to provide accurate control of a permanent magnet (PM) electric motor. The flux estimator may be implemented exclusively in hardware as a hardware flux estimator circuit. The hardware flux estimator circuit is typically specific to a particular model of electric motor. For example, the hardware flux estimator circuit may be tuned to a specific motor type (or variant) to provide optimal control performance. Where there is more than one type (or variant) of the electric motor, a different drive variant may be required to tune the hardware flux estimator circuit. A different drive variant may be required even for different variants of an electric motor within a specific product family. It would be advantageous not to require different drive variants for accurate estimation of the air-gap flux in different motor types, for example to different variants of the electric motor. This would enable the same drive to be used for two or more different types or variants of electric motor.

The use of a software-only solution to estimate the air-gap flux, via an observer, is also known and widely used within industry today. However, the accuracy of a software-only solution may be relatively poor, particularly at low speeds due to the dependency on estimated motor terminal voltage, coupled with measured motor current to estimate the Back electro-motive force (Back EMF) of the motor. At very low speeds, the accuracy of the estimated Back EMF signal can be very poor due to the significant contribution of the tolerances within the inverter power stack, e.g. switching dead-time and dead-time compensation, as a proportion of the very low Back EMF signal. This weakness can be overcome by implementing an open-loop control algorithm or implementing a high frequency injection algorithm to sense magnet position at standstill. The use of these techniques have disadvantages for high speed applications, such as a Turbo Molecular Pump (TMP).

An open-loop Control system is not well suited to TMP applications which are traditionally high speed, high inertia pump systems with low mechanical damping. The low mechanical damping can result in speed over-shoot if the motor is not stiffly controlled by a closed-loop speed and position solution, especially at low-speed. The use of an open-loop control algorithm can therefore be unreliable once the TMP starts to rotate at speeds greater than circa 5 Hz mechanical rotation. It is necessary to initiate rotation via an open-loop algorithm, but it is also imperative that the TMP controller transitions to closed-loop control at very low speeds to overcome the low mechanical damping of the TMP.

High Frequency Injection may be used to characterise the inductance of the stator (Lq and Ld) components of the electric motor. By injecting current at high frequency, the saturation profile of the motor inductance may be determined. The inductance profile is characterised for the complete 360° rotational range of the electric motor. However, this technique requires high levels of current, especially for non-salient pole permanent magnets, to observe the saturation profile. This high current is a design over-head for the inverter power stack and can lead to de-magnetisation of the permanent magnets if the current injection is too high and in the opposite direction to the magnetisation of the permanent magnet.

It is an aim of the present invention to address one or more of the disadvantages associated with the prior art.

The discussion above is merely provided for general background information and is not intended to be used as an aid in determining the scope of the claimed subject matter. The claimed subject matter is not limited to implementations that solve any or all disadvantages noted in the background.

### SUMMARY

Aspects and embodiments of the invention provide a flux estimator; a motor control unit for controlling operation of an electric motor; and a control system as claimed in the appended claims

According to an aspect of the present invention there is provided a flux estimator for estimating an air-gap flux in a permanent magnet electric motor having a rotor and a stator, the flux estimator comprising a resistance compensation stage having a first multiplying digital-to-analogue converter, and an inductance compensation stage having a second multiplying digital-to-analogue converter; wherein the flux estimator is configured to:
determine a first gain for compensating for a stator resistance;
determine a second gain for compensating a stator inductance;
supply the first gain to the first multiplying digital-to-analogue converter in the resistance compensation stage to generate a first output signal providing a scaled representation of the voltage drop across the stator resistance per phase;
supply the second gain to the second multiplying digital-to-analogue converter in the inductance compensation stage to generate a second output signal providing a scaled representation of the stator inductance per phase; and
generate an air-gap flux estimation signal in dependence on the first output and the second output. The flux estimator may be a hardware flux estimator, for example in a flux estimation circuit. The flux estimator may be integrated suitable for use with a plurality of electric motor types (or variants). At least in certain embodiments, the flux estimator may be used without the need for a different circuit variant specific to each motor type. The accuracy of the air-gap flux estimation may be improved compared to prior art flux estimators. At least in certain embodiments, the air-gap flux estimation may be improved at low and very low operating speeds of the electric motor. This may enable improved control of the electric motor.

At least in certain embodiments the first gain and/or the second gain may be determined in dependence on a type (or model) of the electric motor. An identification module may be associated with the electric motor to enable determination of the type. The first gain and/or the second gain for one or more different types of electric motor may be stored, for example in a look-up table or a database. For example, the first gain and/or the second gain The first gain and/or the second gain may be accessed from the look-up table in dependence

The flux estimator may be configured to receive the first gain. The first gain may be received from a control unit, such as a motor control unit. The flux estimator may be configured to receive the second gain. The second gain may be received from a control unit, such as a motor control unit. The control unit may comprise at least one processor configured to execute motor control software. The at least one processor may be configured to output the first gain and/or the second gain.

The voltage drop across the stator resistance may be calculated as a product of the motor phase current and the stator resistance.

The flux estimator may be configured to determine a scaled integral of the voltage difference between a motor terminal voltage and the voltage drop across the stator resistance with respect to time. The air-gap flux estimation signal may be generated in dependence on the determined scaled integral.

The air-gap flux estimation signal may be calculated as a difference between the determined scaled integral and the second output.

The scaled representation of the stator inductance may be a scaled product of the stator inductance and a motor phase current.

The first gain may be defined as follows:

$${K}_{u} = \frac{{V}_{AN}}{{V}_{a}}$$

### Where:

VAN is the phase voltage with respect to an artificial neutral point; and
Va is the motor terminal voltage.
   The second gain may be defined as follows:

$${K}_{La} = \frac{{L}_{a} \cdot {K}_{u} \cdot {k}_{int}}{{K}_{i}}$$

### Where:

La is the stator inductance;
Ku is the first gain;
kint is an integrator gain; and
Ki is the current gain.

The flux estimator may comprise a storage device. At least one data set may be stored on the storage device, for example in a database. The or each data set may comprise a predetermined first gain and/or a predetermined second gain for a permanent magnet electric motor. The flux estimator may be configured to determine the first gain and the second gain by accessing the database.

The flux estimator may be configured to identify the electric motor. The flux estimator may identify a type or a model of the electric motor. The flux estimator may be configured to select the data set corresponding to the identified electric motor to determine the first gain and/or the second gain. The flux estimator may access the storage device to read the data set associated with the identified electric motor.

The flux estimator may be configured to identify the electric motor by supplying current to determine a saturation profile of the motor inductance. The current supplied to the permanent magnet electric motor may be a high frequency current. The flux estimator may be configured to identify the permanent magnet electric motor in dependence on the determined saturation profile.

The flux estimator may be configured to determine the first gain in dependence on an estimated motor terminal voltage; and/or to determine the second gain in dependence on a measured stator inductance. At least in certain embodiments, the first gain and/or the second gain may be determined in dependence on the determined parameters of the electric motor. This may facilitate determination of the first gain and/or the second gain. At least in certain embodiments, the first gain and/or the second gain may be determined without requiring identification of the type or the model of the electric motor.

The flux estimator may be configured to receive at least one signal indicating an operating parameter of the electric motor. The flux estimator may be configured dynamically to modify the first gain and/or the second gain in dependence the or each operating parameter of the electric motor. At least in certain embodiments, the flux estimator may modify the air-gap flux estimation in dependence on the one or more operating parameter. The operating parameter may comprise an operating temperature of the electric motor. Alternatively, or in addition, the operating parameter may comprise an operating speed of the electric motor.

According to an aspect of the present invention there is provided a flux estimator for estimating an air-gap flux in a permanent magnet electric motor having a rotor and a stator, the flux estimator comprising a resistance compensation stage having a multiplying digital-to-analogue converter; wherein the flux estimator is configured to:
determine a gain for compensating for a stator resistance;
supply the gain to the multiplying digital-to-analogue converter in the resistance compensation stage to determine a scaled representation of the voltage drop across the stator resistance per phase;
generate an air-gap flux estimation signal in dependence on the determined scaled representation of the voltage drop across the stator resistance per phase.

The air-gap flux estimation signal may be determined in dependence on a stator inductance per phase. The stator inductance per phase may be predefined or may be calculated, for example by a stator inductance algorithm. Alternatively, the stator inductance per phase may be determined using the techniques described herein.

According to an aspect of the present invention there is provided a flux estimator for estimating an air-gap flux in a permanent magnet electric motor having a rotor and a stator, the flux estimator comprising an inductance compensation stage having a multiplying digital-to-analogue converter; wherein the flux estimator is configured to:
determine a gain for compensating a stator inductance;
supply the gain to the multiplying digital-to-analogue converter in the inductance compensation stage to determine a scaled representation of the stator inductance per phase; and
generate an air-gap flux estimation signal in dependence on the determined scaled representation of the stator inductance per phase.

The air-gap flux estimation signal may be determined in dependence on a voltage drop across the stator resistance per phase. The voltage drop across the stator resistance per phase may be predefined or may be calculated, for example by a voltage drop algorithm. Alternatively, the voltage drop across the stator resistance per phase may be determined using the techniques described herein.

According to a further aspect of the present invention there is provided a motor control unit for controlling operation of an electric motor having a stator and a rotor, the motor control unit comprising at least one processor and a memory device. The at least one processor may be configured to determine a type of the electric motor. In dependence on the determined type of the electric motor, the at least one processor may determine at least one of the following:
a first gain for compensating for a stator resistance of the electric motor; and
a second gain for compensating for a stator inductance of the electric motor.

The at least one processor may be configured to execute motor control software. The motor control software may be embedded in the at least one processor. At least in certain embodiments, the motor control software operate with the flux estimator to estimate the air-gap flux. The accuracy of the air-gap flux estimation may be improved compared to prior art flux estimators. At least in certain embodiments, the air-gap flux estimation may be improved at low and very low operating speeds of the electric motor. This may enable improved control of the electric motor.

The at least one processor may be configured to output the at least one of the first gain and the second gain to a flux estimator. The flux estimator may be of the type described herein.

The at least one processor may be configured to receive one or more operating parameter of the electric motor. The at least one processor may be configured dynamically to modify the at least one of the first gain and the second gain in dependence on the one or more operating parameter of the electric motor.

The control system may comprise a flux estimator as described herein, and a motor control unit as described herein. The motor control unit may be configured to output the at least one of the first gain and the second gain to the flux estimator.

According to a further aspect of the present invention there is provided a pump comprising an electric motor and a motor control unit as described herein. The pump may, for example, be a turbo-molecular pump.

Any control unit or controller described herein may suitably comprise a computational device having one or more electronic processors. The system may comprise a single control unit or electronic controller or alternatively different functions of the controller may be embodied in, or hosted in, different control units or controllers. As used herein the term “controller” or “control unit” will be understood to include both a single control unit or controller and a plurality of control units or controllers collectively operating to provide any stated control functionality. To configure a controller or control unit, a suitable set of instructions may be provided which, when executed, cause said control unit or computational device to implement the control techniques specified herein. The set of instructions may suitably be embedded in said one or more electronic processors. Alternatively, the set of instructions may be provided as software saved on one or more memory associated with said controller to be executed on said computational device. The control unit or controller may be implemented in software run on one or more processors. One or more other control unit or controller may be implemented in software run on one or more processors, optionally the same one or more processors as the first controller. Other suitable arrangements may also be used

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

The Summary is provided to introduce a selection of concepts in a simplified form that are further described in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

One or more embodiments of the invention will now be described, by way of example only, with reference to the accompanying drawings, in which:

FIG. 1 shows a schematic representation of a motor control unit and a flux estimator for controlling operation of an electric motor in accordance with an embodiment of the present invention;

FIG. 2 shows a schematic representation of the motor control unit shown in FIG. 1;

FIG. 3 shows a schematic representation of the flux estimator shown in FIG. 1;

FIG. 4 shows a block diagram representing a terminal voltage estimator of the flux estimator shown in FIG. 3;

FIGS. 5A and 5B shows block diagrams representing a stator resistor gain block of the flux estimator shown in FIG. 3;

FIGS. 6A and 6B shows block diagrams representing a stator resistance compensation and integration gain block of the flux estimator shown in FIG. 3;

FIGS. 7A and 7B shows block diagrams representing a stator inductance compensation and integration gain block of the flux estimator shown in FIG. 3;

FIG. 8 shows a block diagram representing a flux estimation gain block of the flux estimator shown in FIG. 3;

FIG. 9 shows a circuit diagram of a first circuit which operates as a terminal voltage estimator of the flux estimator shown in FIG. 3;

FIG. 10 shows a circuit diagram of a second circuit which operates as a motor stator resistance gain block of the flux estimator;

FIG. 11 shows a circuit diagram of a third circuit which operates to determine a resistance compensation of the flux estimator;

FIG. 12 shows a circuit diagram of a fourth circuit which operates as an integration stage of the flux estimator;

FIG. 13 shows a circuit diagram of a fifth circuit which operates to determine a motor stator inductance gain of the flux estimator 1

FIG. 14 shows a circuit diagram of a sixth circuit which operates to estimate the air-gap flux of the electric motor.

### DETAILED DESCRIPTION

A flux estimator 1 for estimating an air-gap flux in an electric motor 2 in accordance with an embodiment of the present invention is described herein with reference to the accompanying Figures. The flux estimator 1 is implemented in hardware and, at least in certain embodiments, may provide improved accuracy at low operating speeds. Furthermore, the flux estimator 1 may be used for different types or models of the electric motor 2. A motor control unit 3 is provided for controlling the electric motor 2. The flux estimator 1 outputs the estimated air-gap flux to the motor control unit 3. The flux estimator 1 and the motor control unit 3 collectively form a control system 5 for controlling operation of the electric motor 2.

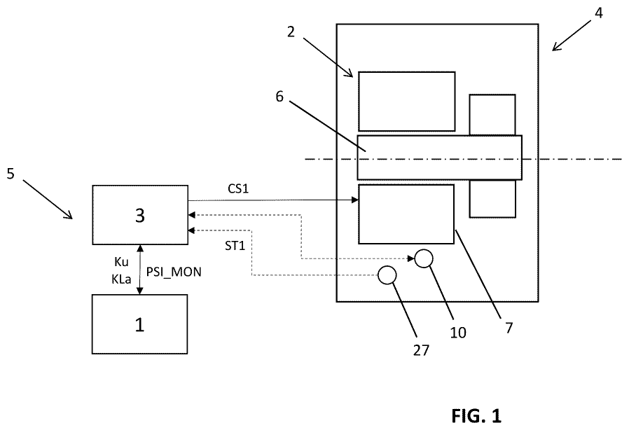

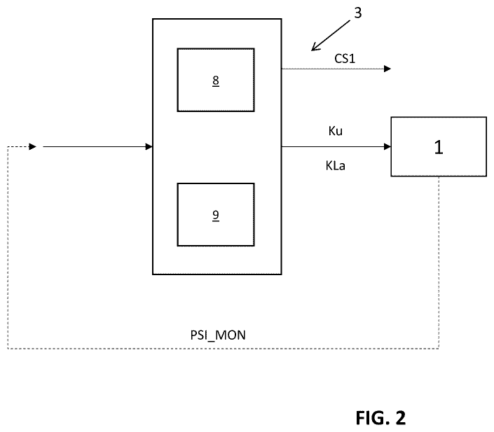

The electric motor 2 in the present embodiment is a drive motor for a turbo-molecular pump (denoted generally by the reference numeral 4). The turbo-molecular pump is operative to pump process gases in an industrial process. It will be understood that the flux estimator 1 can be used to estimate the air-gap flux of electric motors 2 employed in other applications. The electric motor 2 is a permanent magnet (PM) electric motor. A 3-phase alternating current is supplied to the electric motor 2. As shown schematically in FIG. 1, the electric motor 2 comprises a rotor 6 and a stator 7.

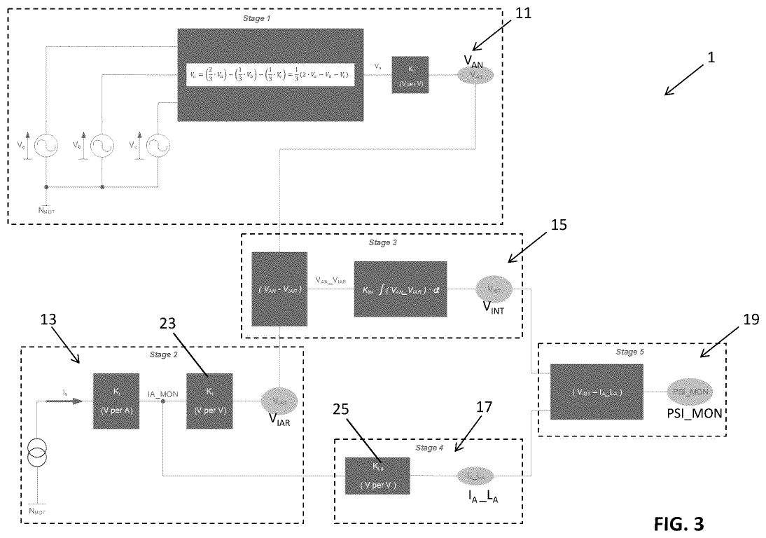

A schematic representation of the motor control unit 3 is shown in FIG. 3. The motor control unit 3 comprises one or more electronic processor 8 and a system memory 9. A set of computational instructions is stored on the system memory 9. When executed by the one or more electronic processor 8, the instructions cause the one or more electronic processor 8 to perform the method(s) described herein. The estimated air-gap flux is output to embedded motor control software executed by the one or more electronic processor provided in the motor control unit 3. In a variant, the flux estimator 1 may be incorporated into the motor control unit 3.

The motor control unit 3 is suitable for use with a plurality of different types of electric motor 2. The different motor types may have different operating characteristics which may require different control strategies. By way of example, the air-gap flux may vary depending on the type of electric motor 2. The flux estimator 1 is configured to estimate the air-gap flux dynamically in dependence on a determined motor type. The motor control unit 3 is configured to identify the electric motor 2 as being one of a plurality of motor types. The motor types are predefined in the present embodiment. The motor types may, for example, correspond to a plurality of different electric motors in a product range. The motor types have different (electrical) operating parameters which may be pre-defined, for example in dependence on empirical data. As described herein, the motor control unit 3 is configured to compensate for the different operating parameters of each of the plurality of motor types.

In the present embodiment, the electric motor 2 comprises an identification module 10 to enable identification of the motor type. The identification module 10 provides an identifier which is specific to each type of electric motor 2. The identification module 10 in the present embodiment comprises a resistor network having at least one resistor. The resistance of the at least one resistor is unique to each type of electric motor 2. By determining the resistance of the identification module 10, the motor control unit 3 can identify the type of the electric motor 2 from a predefined set. The motor control unit 3 is configured to inject a current into the identification module 10. The motor control unit 3 measures the voltage across the identification module 10 and, in dependence on the supplied current, determines the resistance of the one or more resistors. The motor control unit 3 accesses a look-up table to determine the type of the electric motor 2 with reference to the determined resistance. The look-up table in the present embodiment is stored in the system memory 9. The identification module 10 is provided on-board the electric motor 2, for example integrated into an on-board power unit. The motor control unit 3 may be remote from the electric motor 2, for example connected by one or more electrical wires. This configuration can be used to protect the motor control unit 3, for example if the electric motor 2 is to be used in a harsh environment. It will be understood that other techniques may be used to identify the type of electric motor 2.

As described herein, the flux estimator 1 is configured to estimate the air-gap flux in dependence on a first gain to compensate for a stator resistance Ra; and a second gain to compensate for a stator inductance La. The first gain is referred to herein as the resistance gain Ku and the second gain is referred to herein as the inductance gain KLa. The resistance gain Ku and the inductance gain Kla are typically specific to a particular motor type. The motor control unit 3 is configured to determine the resistance gain Ku and the inductance gain KLa in dependence on the determined motor type. The resistance gain Ku and the inductance gain KLa specific to the determined motor type are output to the flux estimator 1. The flux estimator 1 is configured to estimate the air-gap flux in dependence on resistance gain Ku and the inductance gain KLa. The estimated air-gap flux is output from the flux estimator 1 to the motor control unit 3 to enable control of the electric motor 2.

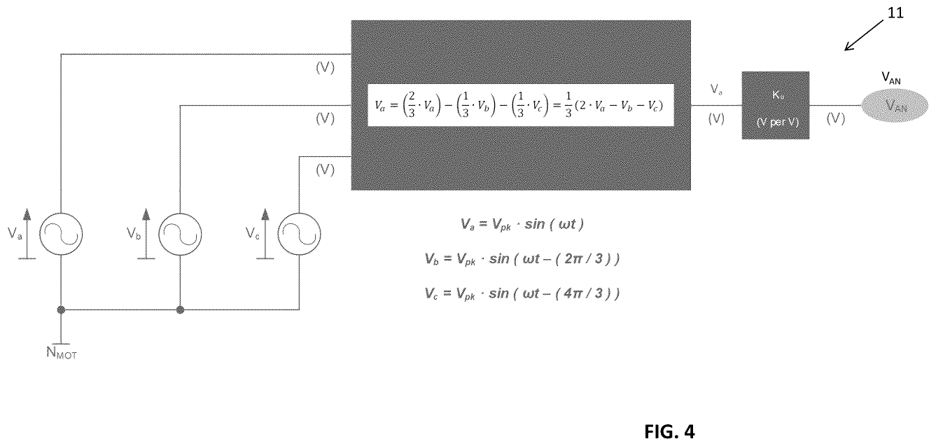

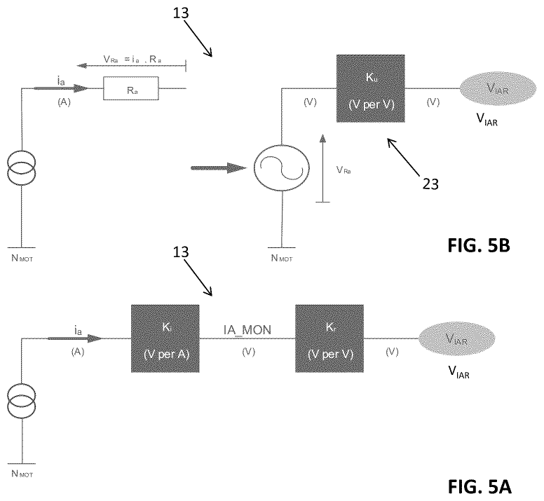

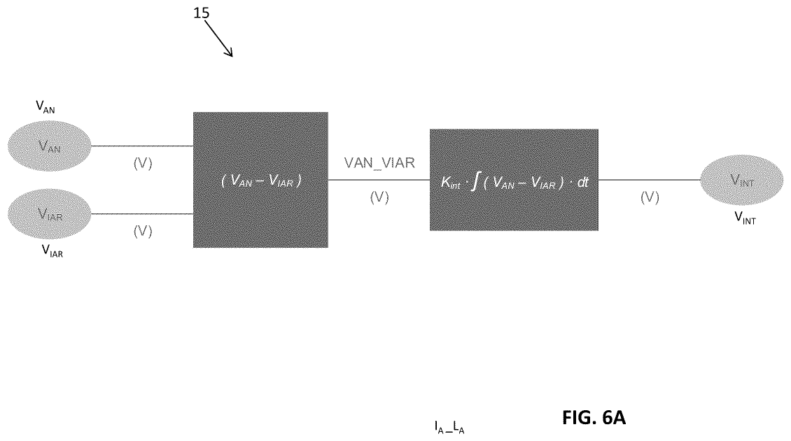

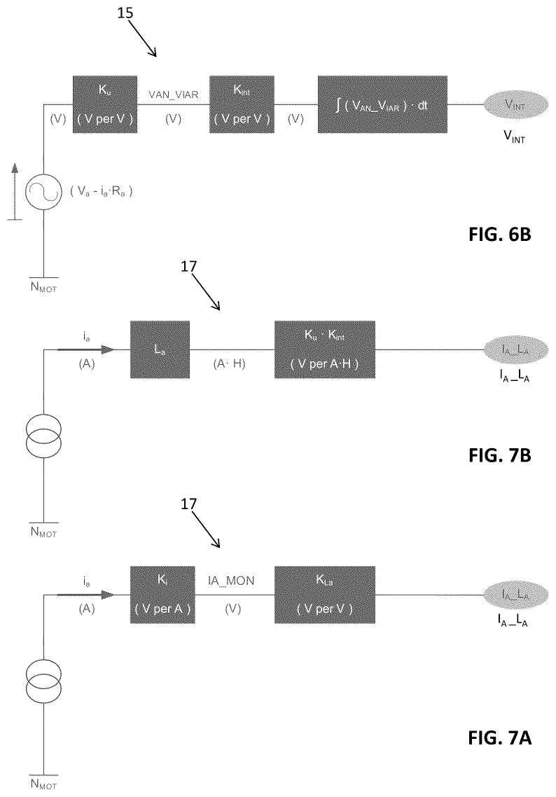

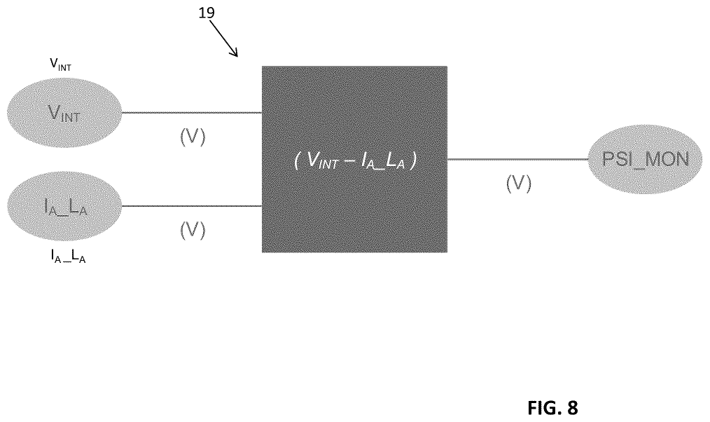

A schematic representation of the flux estimator 1 is shown in FIG. 3. The flux estimator 1 comprises a motor voltage terminal estimator stage 11 (shown in FIG. 4); a motor stator resistance gain stage 13 (shown in FIGS. 5A and 5B), a motor stator resistance compensation and integration stage 15 (shown in FIGS. 6A and 6B); a motor stator inductance gain stage 17 (shown in FIGS. 7A and 7B); and a stator inductance compensation and flux estimation stage 19 (shown in FIG. 8). The motor stator resistance gain stage 13 comprises a first multiplying digital-to-analogue converter (MDAC) 23 for applying a resistance gain Ku to compensate for a stator resistance Ra. The stator inductance compensation stage 19 comprises a second multiplying digital-to-analogue converter (MDAC) 25 for applying an inductance gain KLa to compensate for a stator inductance La.

A schematic representation of the motor voltage terminal estimator stage 11 is shown in FIG. 3. The estimator stage 11 is operative to generate a first signal VAN representing a scaled version of the motor terminal voltage Va. In a balanced three-phase system, the motor terminal voltage Va is defined as the motor terminal voltage with respect to an artificial neutral point. The first signal VAN is defined as: VAN=Ku×Va.

$${V}_{a} = {V}_{p k} \cdot sin ( ω \cdot t )$$

$${V}_{b} = {V}_{p k} \cdot sin ( ω \cdot t - ( \frac{2 \cdot π}{3} ) )$$

$${V}_{c} = {V}_{p k} \cdot sin ( ω \cdot t - ( \frac{4 \cdot π}{3} ) )$$

$${V}_{a} = ( \frac{2}{3} \cdot {V}_{a} ) - ( \frac{1}{3} \cdot {V}_{b} ) - ( \frac{1}{3} \cdot {V}_{c} )$$

$${V}_{a} = \frac{1}{3} ( 2 \cdot {V}_{a} - {V}_{b} - {V}_{c} )$$

$${V}_{AN} = {K}_{u} \cdot {V}_{a}$$

### Where

Va is the motor terminal voltage;
VAN is the scaled motor terminal voltage;
Vpk is the peak voltage; and
Ku is the resistance gain

A schematic representation of the motor stator resistance gain stage 13 is shown in FIGS. 5A and 5B. A stator resistance Ra is determined for the stator 7 of the electric motor 2. The motor stator resistance gain stage 13 applies the resistance gain Ku to the first multiplying digital-to-analogue converter 23 to compensate for a stator resistance Ra. The motor stator resistance gain stage 13 generates a second signal VIAR which represents a scaled version of the motor phase current ia and the stator resistance Ra per phase. The stages in the application of the motor stator resistance gain to determine the scaled motor phase current VIAR are shown in FIG. 5B.

$${V}_{IAR} = {K}_{u} \times {i}_{a} \times {R}_{a} = {K}_{r} \times {K}_{i} \times {i}_{a}$$

$${V}_{AN} = {K}_{u} \cdot {V}_{a}$$

$${V}_{IAR} = {K}_{u} \cdot {V}_{Ra} = {K}_{u} \cdot ( {i}_{a} \cdot {R}_{a} )$$

$${V}_{AN} - {V}_{IAR} = {K}_{u} \cdot [ {V}_{a} - {i}_{a} \cdot {R}_{a} ]$$

$${V}_{IAR} = {K}_{i} \cdot {K}_{r} \cdot {i}_{a} = {K}_{u} \cdot {i}_{a} \cdot {R}_{a}$$

$${K}_{r} = \frac{{K}_{u} \cdot {i}_{a} \cdot {R}_{a}}{{K}_{i} \cdot {i}_{a}} = \frac{{K}_{u}}{{K}_{i}} \cdot {R}_{a}$$

### Where

VIAR is the scaled motor phase current;
la is the motor phase current;
Ra is the stator resistance (per phase);
Ku is the resistance gain;
Kr is the stator resistance compensation gain; and
Ki is the current gain.

The scaled motor terminal voltage VAN and the scaled motor phase current VIAR are output to the resistance compensation and integration stage 15. As shown in FIGS. 6A and 6B, the resistance compensation and integration stage 15 generates a third signal VINT representing a scaled integral of the motor terminal voltage Vₐ minus the voltage drop across the motor stator resistance VIAR. The determination of the voltage difference and the application of the integrator gain Kint to determine the scaled integral of the motor terminal voltage VINT are shown in FIG. 6B. The signal is scaled (by an integrator gain Kint.

$$VAN\_VIAR = {V}_{AN} - {V}_{IAR} = {K}_{u} \cdot [ {V}_{a} - ( {i}_{a} \cdot {R}_{a} ) ]$$

$${V}_{INT} = {K}_{int} \cdot \int ( {V}_{AN -} {V}_{IAR} ) \cdot dt$$

### Where

VINT is the scaled integral of the motor terminal voltage;
Ia is the motor phase current;
Ra is the stator resistance (per phase);
Ku is the resistance gain; and
Kint is the integrator gain.

The motor stator inductance gain stage 17 generates a fourth signal I_{A}_L_{A}. As shown in FIGS. 7A and 7B, the fourth signal I_{A}_L_{A} represents a scaled version of the product of the motor phase current ia and the stator inductance La per phase: I_{A}_L_{A}=Kᵤ×iₐ×Lₐ×Kᵢₙ. The inductance gain KLa is applied to the second MDAC 25 to scale the product of the motor phase current ia and the stator inductance La. The stages in the determination of the scaled product I_{A}_L_{A} are shown in FIG. 7B.

$${I}_{A -} LA = {i}_{a} \cdot {L}_{a} \cdot {K}_{u} \cdot {K}_{int}$$

$${I}_{A -} LA = {i}_{a} \cdot {K}_{i} \cdot {K}_{La}$$

$${i}_{a} \cdot {L}_{a} \cdot {K}_{u} \cdot {K}_{int} = {i}_{a} \cdot {K}_{i} \cdot {K}_{La}$$

$${K}_{La} = \frac{{L}_{a} \cdot {K}_{u} \cdot {k}_{int}}{{K}_{i}}$$

### Where

L_{A}_L_{A} is the scaled product of the motor phase current and the stator inductance;
Ia is the motor phase current;
La is the stator inductance (per phase);
Ku is the resistance gain
Kint is the integrator gain;
Ki is the current gain; and
KLA is the inductance gain.

The flux estimation stage 19 generates a fifth signal PSI_MON corresponding to the air-gap flux estimation signal PSI_MON. The determination of the air-gap flux estimation signal PSI_MON is illustrated in FIG. 8. The air-gap flux estimation signal PSI_MON represents a scaled estimation of the motor air-gap flux. The air-gap flux estimation is calculated as the difference between the determined scaled integral VINT and the fourth signal I_{A}_L_{A}. PSI_MON=V_{INT}−L_{A}_L_{A}.

$$PSI\_MON = {V}_{INT} - {I}_{A -} {L}_{A}$$

### Where

PSI_MON is the air-gap flux estimation signal;
VINT is the scaled integral of the motor terminal voltage; and
L_{A}_L_{A} is the scaled product of the motor phase current and the stator inductance.

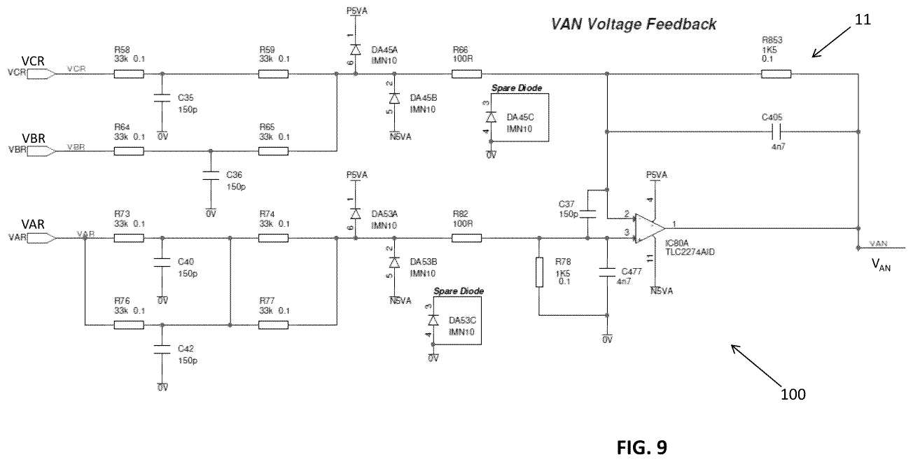

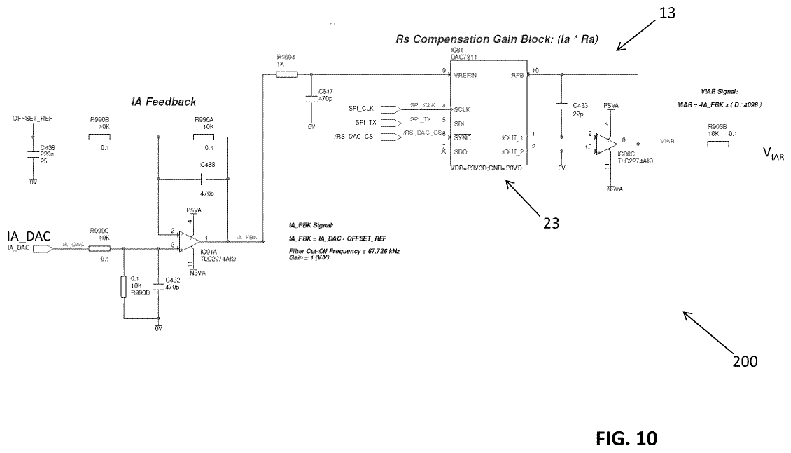

A first circuit 100 provides the motor terminal voltage estimator stage 11 of the flux estimator 1. The first circuit 100 is shown in FIG. 9. The estimator stage 11 receives voltage signals VAR, VBR, VCR corresponding to the respective phase voltages supplied the electric motor 2. The estimator stage 11 outputs the first signal VAN representing the scaled motor terminal voltage Va. The first signal VAN is output to the resistance compensation and integration stage 15.

A second circuit 200 provides the motor stator resistance gain stage 13 of the flux estimator 1. The second circuit 200 is shown in FIG. 10. The motor stator resistance gain stage 13 subtracts a reference offset OFFSET_REF from the motor phase current ia to determine a stator current feedback signal IA_FBK. The signal is filtered and output to the first multiplying digital-to-analogue converter 23. The product of the motor phase current ia and the stator resistance Ra is calculated to determine the voltage drop across the motor stator resistance. The resistance gain Ku is supplied to the first multiplying digital-to-analogue converter 23 to compensate for the stator resistance Ra. The first multiplying digital-to-analogue converter 23 scales the product of the motor phase current ia and the stator resistance Ra by applying the resistance gain Ku to generate the second signal VIAR per phase. The motor stator resistance gain stage 13 outputs the scaled second signal VIAR.

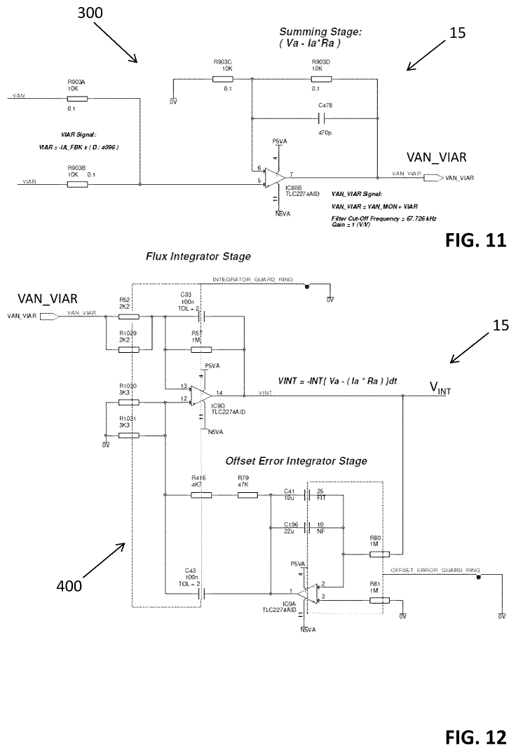

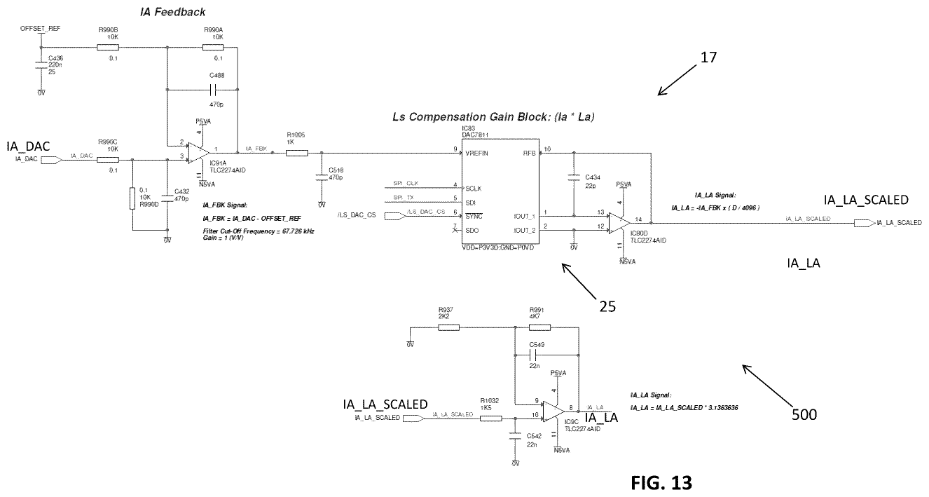

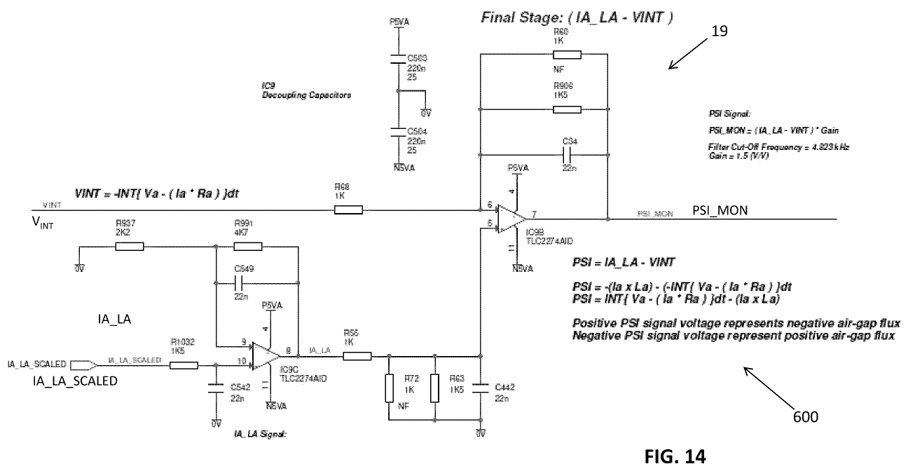

A third circuit 300 and a fourth circuit 400 provide the resistance compensation and integration stage 15 of the flux estimator 1. The third and fourth circuits 300, 400 are shown in FIGS. 11 and 12 respectively. The third circuit 300 is a summing stage operative to subtract the first signal VAN (received from the estimator stage 11) from the second signal VIAR (received from the motor stator resistance gain stage 13). A first gain Ku is applied to the calculation to generate an output signal VAN_VIAR. The output signal VAN_VIAR from the third circuit 300 is supplied as an input to the fourth circuit 400. The fourth circuit 400 comprises a flux integrator stage 410 which integrates the signal VAN_VIAR with respect to time. The signal is scaled by an integral gain Kint. The scaled integrated signal VINT is output from the fourth circuit 400. The fourth circuit 400 in the present embodiment also comprises an offset error integrator stage 420.

A fifth circuit 500 provides the motor stator inductance gain stage 17 of the flux estimator 1. The fifth circuit 500 is shown in FIG. 13. The fifth circuit 500 comprises the second MDAC 25. The product of the motor phase current ia and the stator inductance La per phase is determined and the result is scaled by the inductance gain KLa supplied to the second MDAC 25. The fifth circuit 500 outputs the fourth signal I_{A}_L_{A} representing the scaled product of the motor phase current ia and the stator inductance La per phase.

A sixth circuit 600 provides the flux estimation stage 19 of the flux estimator 1. The sixth circuit 600 receives the scaled integral VINT from the resistance compensation and integration stage 15; and the second output IA_LA from the motor stator inductance gain stage 17. The sixth circuit 600 subtracts the second output IA_LA from the scaled integral VINT and outputs the signal PSI_MON representing the air-gap flux estimation. A positive (+ve) PSI signal voltage represents a negative (−ve) air-gap flux; and a negative (−ve) PSI signal voltage represents a positive (+ve) air-gap flux.

The signal PSI_MON representing the air-gap flux estimation is output from the flux estimator 1 to the motor control unit 3. The motor control unit 3 is configured to control operation of the electric motor 2 in dependence on the estimated air-gap flux. The motor control unit 3 may, for example, output a control signal CS1 (shown schematically in FIG. 1) to control operation of the electric motor 2.

The flux estimator 1 provides a hybrid system utilising a combination of hardware and software to estimate the air-gap flux. The flux estimator 1 offers particular advantages in relation to the operation of a pump, such as the turbo-molecular pump 3 described herein. At least in certain embodiments, the flux estimator 1 may provide one or more of the following:
Transition from open-loop to closed-loop control at very low speeds, circa 5 Hz, corresponding to approximately 1% speed.
Hardware measurement of the motor terminal voltage
Flexible/tuneable gain block to enable dynamic, software tuning of the resistance and inductance compensation stages within the flux estimator circuit topology.
Suitability for multiple motor variants without the need for multiple Drive hardware variants.

In the above embodiment, the resistance gain Ku and/or the inductance gain KLa are selected in dependence on the determined type of the electric motor 2. The resistance gain Ku and/or the inductance gain KLa may optionally be varied in dependence on one or more operating parameters of the electric motor 2. The flux estimator 1 or the motor control unit 3 may modify the resistance gain Ku and/or the inductance gain KLa in dependence on the one or more operating parameter. The resistance gain Ku and/or the inductance gain KLa may be modified to compensate for one or more changing operating parameters of the electric motor 2. The resistance gain Ku and/or the inductance gain KLa may, for example, be varied in dependence on a temperature of the electric motor 2. The temperature of the electric motor 2 may be modelled or may be measured by one more temperature sensor 27 shown schematically in FIG. 1. The flux estimator 1 may provide a dynamic estimation of the air-gap flux which is varied in dependence on the one or more operating parameters of the electric motor 2. A temperature signal ST1 may be output to the motor control unit 3. The motor control unit 3 may modify the resistance gain Ku and/or the inductance gain KLa in dependence on the determined temperature of the electric motor 2.

It will be appreciated that various changes and modifications can be made to the present invention without departing from the scope of the present application.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. A flux estimator for estimating an air-gap flux in a permanent magnet electric motor having a rotor and a stator, the flux estimator comprising a resistance compensation stage having a first multiplying digital-to-analogue converter, and an inductance compensation stage having a second multiplying digital-to-analogue converter; wherein the flux estimator is configured to:
determine a first gain (Ku) for compensating for a stator resistance (Ra);
determine a second gain (KLa) for compensating a stator inductance (La);
supply the first gain (Ku) to the first multiplying digital-to-analogue converter in the resistance compensation stage to generate a first output signal (VIAR) providing a scaled representation of the voltage drop across the stator resistance (Ra) per phase;
supply the second gain (KLa) to the second multiplying digital-to-analogue converter in the inductance compensation stage to generate a second output signal (IA_LA) providing a scaled representation of the stator inductance (La) per phase; and
generate an air-gap flux estimation signal (PSI_MON) in dependence on the first output (VIAR) and the second output (IA_LA).

2. The flux estimator as claimed in claim 1, wherein determining the first gain (Ku) comprises receiving the first gain (Ku) from a control unit; and/or determining a second gain (KLa) comprises receiving the second gain (KLa) from a control unit.

3. The flux estimator as claimed in claim 1, wherein the voltage drop across the stator resistance (Ra) is the product of the motor phase current (ia) and the stator resistance (Ra).

4. The flux estimator as claimed in claim 3, wherein the flux estimator is configured to:
determine a scaled integral (VINT) of the voltage difference between a motor terminal voltage (VAN) and the voltage drop across the stator resistance (VIAR) with respect to time.

5. The flux estimator as claimed in claim 4, wherein the air-gap flux estimation signal (PSI_MON) is generated in dependence on the determined scaled integral (VINT).

6. The flux estimator as claimed in claim 5, wherein the air-gap flux estimation signal (PSI_MON) is calculated as the difference between the determined scaled integral (VINT) and the second output (IA_LA).

7. The flux estimator as claimed in claim 1, wherein the scaled representation of the stator inductance (La) is a scaled product of the stator inductance (La) and a motor phase current (Ia).

8. The flux estimator as claimed in claim 1, wherein the first gain (Ku) is defined as follows:
$${K}_{u} = \frac{{V}_{AN}}{{V}_{a}}$$
Where:
VAN is the phase voltage with respect to an artificial neutral point; and
Va is the motor terminal voltage.

9. The flux estimator as claimed in claim 1, wherein the second gain (KLa) is defined as follows:
$${K}_{La} = \frac{{L}_{a} \cdot {K}_{a} \cdot {k}_{int}}{{K}_{i}}$$
Where:
La is the stator inductance;
Ku is the first gain;
kint is an integrator gain; and
Ki is the current gain.

10. The flux estimator as claimed in claim 1 comprising a storage device, wherein a database comprising at least one data set is stored on the storage device, the or each data set comprising predetermined first and second gains for the electric motor; the flux estimator being configured to determine the first gain and the second gain by accessing the database.

11. The flux estimator as claimed in claim 10, wherein the flux estimator is configured to identify the electric motor and to select the data set corresponding to the identified electric motor to determine the first and second gains.

12. The flux estimator as claimed in claim 11, wherein the flux estimator is configured to identify the electric motor by supplying current to determine a saturation profile of the motor inductance; the flux estimator being configured to identify the electric motor in dependence on the determined saturation profile.

13. The flux estimator as claimed in claim 1, wherein the flux estimator is configured to determine the first gain (Ku) in dependence on an estimated motor terminal voltage (Va); and/or to determine the second gain (KLa) in dependence on a measured stator inductance (La).

14. The flux estimator as claimed in claim 1, wherein the flux estimator is configured to receive at least one signal indicating an operating parameter of the electric motor; the flux estimator being configured dynamically to modify the first gain (Ku) and/or the second gain (KLa) in dependence on the or each operating parameter of the electric motor.

15. The flux estimator as claimed in claim 14, wherein the one or more operating parameter comprise an operating temperature of the electric motor.

16. A motor control unit for controlling operation of an electric motor having a stator and a rotor, the motor control unit comprising at least one processor and a memory device, the at least one processor being configured to determine a type of the electric motor and, in dependence on the determined type of the electric motor, to determine at least one of the following:
a first gain (Ku) for compensating for a stator resistance (Ra) of the electric motor; and
a second gain (KLa) for compensating for a stator inductance (La) of the electric motor.

17. The motor control unit as claimed in claim 16, wherein the at least one processor is configured to output the at least one of the first gain (Ku) and the second gain (KLa) to a flux estimator comprising a resistance compensation stage having a first multiplying digital-to-analogue converter, and an inductance compensation stage having a second multiplying digital-to-analogue converter.

18. The motor control unit as claimed in claim 16, wherein the at least one processor is configured to receive one or more operating parameter of the electric motor; the at least one processor being configured dynamically to modify the at least one of the first gain (Ku) and the second gain (KLa) in dependence on the one or more operating parameter of the electric motor.

19. A control system comprising a flux estimator as claimed in claim 1, and a motor control unit for controlling operation of the electric motor, the motor control unit comprising at least one processor and a memory device, the at least one processor being configured to determine a type of the electric motor and, in dependence on the determined type of the electric motor, to determine at least one of the following:
a first gain (Ku) for compensating for a stator resistance (Ra) of the electric motor; and
a second gain (KLa) for compensating for a stator inductance (La) of the electric motor; wherein the motor control unit is configured to output the at least one of the first gain (Ku) and the second gain (KLa) to the flux estimator.

20. A pump comprising an electric motor and a motor control unit as claimed in claim 16.
